(19) United States
(12) Patent Application Publication
(10) Pub. No.: US 2024/0069869 A1
(43) Pub. Date: Feb. 29, 2024

(54) MULTIPLY-ACCUMULATE OPERATION DEVICE AND NEURAL NETWORK

(71) Applicant: SONY SEMICONDUCTOR SOLUTIONS CORPORATION, KANAGAWA (JP)

(72) Inventor: MASANORI TSUKAMOTO, KANAGAWA (JP)

(21) Appl. No.: 18/258,278

(22) PCT Filed: Dec. 16, 2021
(86) PCT No.: PCT/JP2021/046621

§ 371 Date: Jun. 19, 2023

(30) Foreign Application Priority Data
Dec. 25, 2020 (JP) 2020-217286

(51) Int. Cl. G06F 7/544; G06N 3/063; G11C 11/22; G11C 11/54

(52) U.S. Cl. CPC G06F 7/5443; G06N 3/063; G11C 11/221; G11C 11/54

(57) ABSTRACT

A multiply-accumulate operation device according to an aspect of the present disclosure includes multiple cells each including a transistor and a ferroelectric capacitor that is coupled to a first source and drain terminal of the transistor. The multiple cells are arranged in rows and columns. This multiply-accumulate operation device further includes multiple input wiring lines and multiple output wiring lines. Each unit of one or more of the multiple input wiring lines is assigned to corresponding one of the rows of the multiple cells. The multiple input wiring lines are coupled to the ferroelectric capacitors. Each of the multiple output wiring lines is assigned to corresponding one of the columns of the multiple cells. The multiple output wiring lines are coupled to second source and drain terminals of the transistors. The multiple output wiring lines are each configured to store an amount of electric charge corresponding to a product of capacitance of the ferroelectric capacitor of each of the cells and an input voltage supplied to the input wiring line.

### TECHNICAL FIELD

The present disclosure relates to a multiply-accumulate operation device using a ferroelectric capacitor and to a neural network.

### BACKGROUND ART

Recently, a neural network circuit is practically used as an application for image recognition and pattern recognition. It is expectable that an issue in Neumann-type computing, such as a delay between a memory and a CPU or electric power consumption, is to be solved by utilizing a memory array for a multiply-accumulate operation in the neural network circuit. Examples of the multiply-accumulate operation include, for example, methods disclosed in PTLs 1 to 3.

### CITATION LIST

### Patent Literature

PTL 1: Japanese Unexamined Patent Application Publication No. 2018-120433
PTL 2: Japanese Unexamined Patent Application Publication No. 2019-219990
PTL 3: Japanese Unexamined Patent Application Publication No. 2019-179499

### SUMMARY OF THE INVENTION

Incidentally, in the inventions disclosed in PTLs 1 and 2 described above, because a parameter (a weight) is stored in a volatile capacitive coupling memory, it is difficult to hold the parameter. Further, in the invention disclosed in PTL 3 described above, because a parameter is stored in a ferroelectric transistor, the number of times of writing (the number of times of rewriting the parameter) is limited, which is not acceptable for practical use. It is therefore desirable to provide a multiply-accumulate operation device and a neural network that are able to hold a parameter and also able to perform writing for the number of times acceptable for practical use.

A multiply-accumulate operation device according to a first aspect of the present disclosure includes multiple cells each including a transistor and a ferroelectric capacitor that is coupled to a first source and drain terminal of the transistor. The multiple cells are arranged in rows and columns. This multiply-accumulate operation device further includes multiple input wiring lines and multiple output wiring lines. Each unit of one or more of the multiple input wiring lines is assigned to corresponding one of the rows of the multiple cells. The multiple input wiring lines are coupled to the ferroelectric capacitors. Each of the multiple output wiring lines is assigned to corresponding one of the columns of the multiple cells. The multiple output wiring lines are coupled to second source and drain terminals of the transistors. The multiple output wiring lines are each configured to store an amount of electric charge corresponding to a product of capacitance of the ferroelectric capacitor of each of the cells and an input voltage supplied to the input wiring line.

A neural network according to a second aspect of the present disclosure includes multiple multiply-accumulate operation devices. Each of the multiply-accumulate operation devices includes elements similar to those of the multiply-accumulate operation device according to the first aspect described above.

In the multiply-accumulate operation device according to the first aspect of the present disclosure and the neural network according to the second aspect of the present disclosure, the ferroelectric capacitor is provided in the cell. This allows a parameter (a weight) to be held in the ferroelectric capacitor. Here, in a case where the variation in load capacitance of the cells is great, the variation causes a noise at the time of inference. This can decrease accuracy of the inference. However, in the present disclosure, the variation in the load capacitance of the ferroelectric capacitors that each hold the parameter (the weight) is small. It is therefore possible to perform the inference with high accuracy. In addition, the upper limit of the number of times of rewriting in the ferroelectric capacitor is extremely large as compared with a case of using another memory (for example, a ReRAM). Thus, the ferroelectric capacitor practically has no limit in the number of times of rewriting.

A multiply-accumulate operation device according to a third aspect of the present disclosure includes multiple cells arranged in rows and columns. The cells each include a main cell and a reference cell. The main cell includes a first transistor and a first ferroelectric capacitor that is coupled to a first source and drain terminal of the first transistor. The reference cell includes a second transistor and a second ferroelectric capacitor that is coupled to a second source and drain terminal of the second transistor. This multiply-accumulate operation device further includes multiple input wiring lines, multiple first output wiring lines, and multiple second output wiring lines. Each unit of one or more of the multiple input wiring lines is assigned to corresponding one of the rows of the multiple cells. The multiple input wiring lines are coupled to the first ferroelectric capacitors and the second ferroelectric capacitors. Each of the multiple first output wiring lines is assigned to corresponding one of the columns of the multiple cells. The multiple first output wiring lines are coupled to third source and drain terminals of the first transistors. The multiple first output wiring lines are each configured to store an amount of electric charge corresponding to a product of capacitance of the first ferroelectric capacitor of each of the main cells and an input voltage supplied to the input wiring line. Each of the multiple second output wiring lines is assigned to corresponding one of the columns of the multiple cells. The multiple second output wiring lines are coupled to fourth source and drain terminals of the second transistors. The multiple second output wiring lines are each configured to store an amount of electric charge corresponding to a product of capacitance of the second ferroelectric capacitor of each of the reference cells and the input voltage supplied to the input wiring line.

A neural network according to a fourth aspect of the present disclosure includes multiple multiply-accumulate operation devices. Each of the multiply-accumulate operation devices includes elements similar to those of the multiply-accumulate operation device according to the third aspect described above.

In the multiply-accumulate operation device according to the third aspect of the present disclosure and the neural network according to the fourth aspect of the present disclosure, the ferroelectric capacitor is provided in each of the first cell and the second cell. This allows a parameter (a weight) to be held in the ferroelectric capacitor. Here, in a case where the variation in load capacitance of the cells is great, the variation causes a noise at the time of inference. This can decrease accuracy of the inference. However, in the present disclosure, the variation in the load capacitance of the ferroelectric capacitors that each hold the parameter (the weight) is small. It is therefore possible to perform the inference with high accuracy. In addition, the upper limit of the number of times of rewriting in the ferroelectric capacitor is extremely large as compared with a case of using another memory (for example, a ReRAM). Thus, the ferroelectric capacitor practically has no limit in the number of times of rewriting.

### BRIEF DESCRIPTION OF DRAWINGS

FIG. 1 is a schematic diagram illustrating an example of a neural network.

FIG. 2 is a diagram illustrating an example of a configuration of a multiply-accumulate operation device according to a first embodiment of the present disclosure.

FIG. 3 is a diagram illustrating an example of a relationship between an input voltage and polarization of each cell in a multiply-accumulate operation circuit of FIG. 2.

FIG. 4 is a diagram illustrating an example of a plan layout of the multiply-accumulate operation circuit of FIG. 2.

FIG. 5 is a diagram illustrating an example of a neural network using the multiply-accumulate operation circuit of FIG. 2.

FIG. 6 is a diagram illustrating an example of a multiply-accumulate operation device according to a second embodiment of the present disclosure.

FIG. 7 is a diagram illustrating an example of a circuit configuration of a memory cell of FIG. 6.

FIG. 8 is a diagram illustrating an example of a plan layout of a multiply-accumulate operation circuit of FIG. 6.

FIG. 9 is a diagram illustrating an example of a neural network using the multiply-accumulate operation circuit of FIG. 6.

FIG. 10 is a diagram illustrating a modification of the circuit configuration of the memory cell of FIG. 6.

FIG. 11 is a diagram illustrating an example of a read voltage in a multiply-accumulate operation circuit including the memory cell of FIG. 10.

FIG. 12 is a diagram illustrating an example of the read voltage in the multiply-accumulate operation circuit including the memory cell of FIG. 10.

### MODES FOR CARRYING OUT THE INVENTION

In the following, embodiments for carrying out the present disclosure are described in detail with reference to the drawings. Note that, in the present description and the drawings, components that have substantially the same functional configuration are denoted by the same reference signs, and redundant description thereof is thus omitted.

### 1. Technical Background Related to Present Disclosure

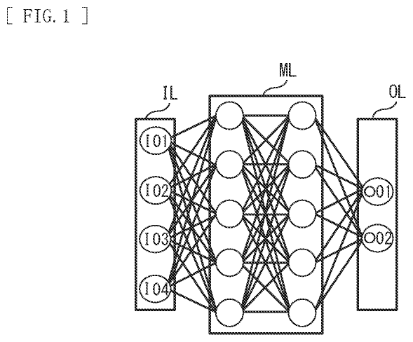

First, referring to FIG. 1, the technical background related to the present disclosure is described. A neural network is an information processing system modeled on a biological neural network. The neural network is able to efficiently execute operations that can be heavy loads for a digital calculator, such as image recognition, image compression, or image decompression. One example of such a neural network may be a perceptron in which artificial neurons arranged in layers are coupled to each other only between adjacent layers and information is propagated only in one direction from an input side to an output side.

FIG. 1 illustrates an example of a neural network. The neural network includes, for example, an input layer IL, a middle layer ML (a hidden layer), and an output layer OL. Each of the layers (IL, ML, and OL) includes one or multiple neurons. For example, the number of neurons in the input layer IL is settable in accordance with the number of pixels included in moving image data. The number of neurons in the middle layer ML is settable as appropriate. The output layer OL is settable in accordance with the number required in subsequent stages.

Neurons in mutually adjacent layers are coupled to each other, and a weight (a coupling load) is set for each coupling. The number of couplings of neurons may be set as appropriate. A threshold is set for each neuron. For example, respective output values of the neurons are determined depending on whether or not the sum of respective products of input values and weights of the neurons exceeds a threshold.

### 2. First Embodiment

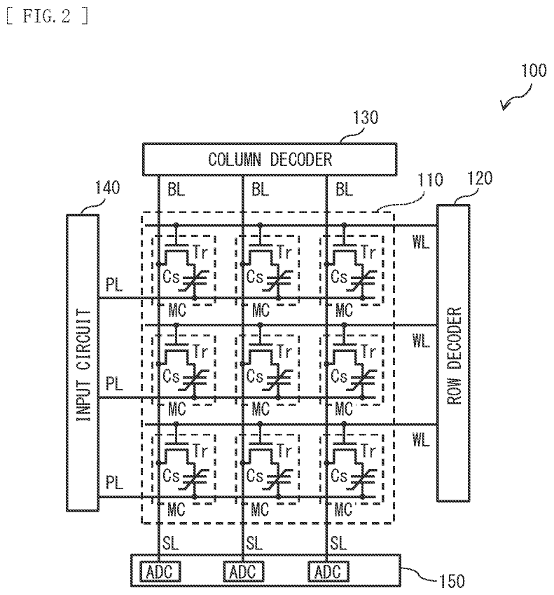

Next, a description is given of a multiply-accumulate operation device 100 according to a first embodiment of the present disclosure. FIG. 2 illustrates an example of a configuration of the multiply-accumulate operation device 100. The multiply-accumulate operation device 100 includes a multiply-accumulate operation circuit 110, a row decoder 120, a column decoder 130, an input circuit 140, and an output circuit 150. The multiply-accumulate operation circuit 110 includes multiple cells MC that are coupled to each other in rows and columns. The multiple cells MC correspond to synapses. The multiply-accumulate operation circuit 110 is driven by the row decoder 120, the column decoder 130, and the input circuit 140. The multiply-accumulate operation circuit 110 is provided on a silicon substrate, for example.

Multiple word lines WL are coupled to the row decoder 120. The multiple word lines WL are assigned with respect to the multiple cells MC arranged in rows and columns, for example, in such a manner that each of the multiple word lines WL is assigned to corresponding one of the rows. Multiple bit lines BL are coupled to the column decoder 130. The multiple bit lines BL are assigned with respect to the multiple cells MC arranged in rows and columns, for example, in such a manner that each of the multiple bit lines BL is assigned to corresponding one of the columns. Multiple input wiring lines PL are coupled to the input circuit 140. The multiple input wiring lines PL are assigned with respect to the multiple cells MC arranged in rows and columns, for example, in such a manner that each of the multiple input wiring lines PL is assigned to corresponding one of the rows. Multiple output wiring lines SL are each coupled to corresponding one of the bit lines BL. The bit line BL and the output wiring line SL are configured to store an amount of electric charge corresponding to a product of capacitance of a ferroelectric capacitor Cs of each of the cells MC and an input voltage supplied to the input wiring line PL.

The row decoder 120 selects a cell MC to be accessed by applying a selection signal to the word line WL. The selection signal is a pulse having a peak value higher than or equal to a threshold voltage of a transistor Tr (which will be described later) in the cell MC. In the cell MC selected by the row decoder 120, the transistor Tr is brought into a conductive state (is turned on). The column decoder 130 supplies a predetermined voltage Vb1 to each of the cells MC coupled to the bit line BL by applying the predetermined voltage Vb1 to the bit line BL. The input circuit 140 supplies a predetermined voltage (an input voltage Vp1) to each of the cells MC coupled to the input wiring line PL by applying the predetermined voltage (the input voltage Vp1) to the input wiring line PL. A voltage corresponding to a difference between the input voltage Vp1 applied to the input wiring line PL and the voltage Vb1 applied to the bit line BL is applied to each of the cells MC. Here, assume that, in a case where the input voltage Vp1 is a predetermined positive voltage, the voltage Vb1 is, for example, a ground voltage (0 V). In this case, for example, “0” is stored in the cell MC as a polarization state of the cell MC. In addition, assume that the voltage Vb1 is a predetermined positive voltage in a case where the input voltage Vp1 is the ground voltage (0 V). In this case, for example, “1” is stored in the cell MC as the polarization state of the cell MC.

The input voltage Vp1 is applied to the cell MC from the input circuit 140 through the input wiring line PL, and the voltage Vb1 is applied to the cell MC from the column decoder 130 through the bit line BL. As a result, a switching current corresponding to the polarization of the ferroelectric body of the cell MC flows through the cell MC. The output of each of the cells MC is coupled to the output wiring line SL via the bit line BL. The output circuit 150 acquires a multiply-accumulate operation result by measuring a current flowing through the output wiring line SL or a potential of the output wiring line SL. For example, the output circuit 150 includes an AD (Analog-to-Digital) conversion circuit that measures the respective voltages of the output wiring lines SL at the same time and in parallel, and outputs, to an outside, a digital signal obtained by performing AD conversion on the multiply-accumulate operation result. Note that the output circuit 150 may further include an amplifier circuit or the like on an as-needed basis.

The multiply-accumulate operation circuit 110 includes the multiple cells MC arranged in rows and columns. Each of the cells MC has, for example, a 1Tr1C circuit configuration that is configured to include the transistor Tr and a ferroelectric capacitor Cs coupled to a source and drain terminal of the transistor Tr. The transistor Tr is a MOSFET, for example. The ferroelectric capacitor Cs has a configuration in which a ferroelectric material is sandwiched between a pair of electrodes. Examples of the ferroelectric material include hafnium oxide (HfOx), zirconium oxide (ZrOx), hafnium zirconium oxide (HfZrOx), and the like. It is possible to cause hafnium oxide (HfOx), zirconium oxide (ZrOx), hafnium zirconium oxide (HfZrOx), and the like to be ferroelectric bodies by performing crystallization annealing on these materials. The ferroelectric material may be doped with an atom of La, Si, Gd, or the like. For example, titanium nitride (TiN), tantalum nitride (TaN), or the like may be used for an electrode of the ferroelectric capacitor Cs.

A gate of the transistor Tr is coupled to the word line WL, and receives a signal from the row decoder 120 via the word line WL. One source and drain terminal of the transistor Tr is coupled to the input wiring line PL via the ferroelectric capacitor Cs. One terminal of the ferroelectric capacitor Cs is coupled to the one source and drain terminal of the transistor Tr, and another terminal of the ferroelectric capacitor Cs is coupled to the input wiring line PL. The one source and drain terminal of the transistor Tr receives a signal from the input circuit 140 via the ferroelectric capacitor Cs. The bit line BL is coupled to the other source and drain terminal of the transistor Tr, and the other source and drain terminal of the transistor Tr receives a signal from the column decoder 130 via the bit line BL.

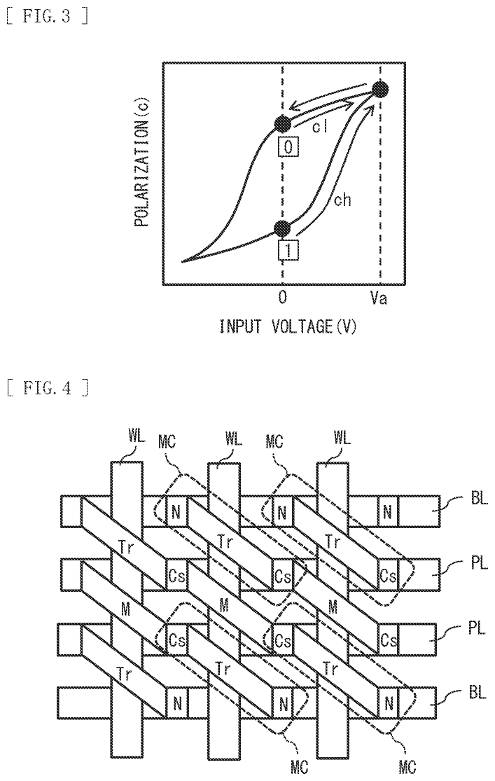

In the multiply-accumulate operation circuit 110, for example, when the voltage (the input voltage Vp1) is applied to the input (the input wiring line PL) of the cell MC selected by the row decoder 120, an amount of electric charge corresponding to the product of the capacitance of the ferroelectric capacitor Cs and the input voltage Vp1 is stored in the output wiring line SL. It is thus possible to perform a multiply-accumulate operation. For example, in inference of the multiply-accumulate operation, when the voltage (the input voltage Vp1) is applied to the input (the input wiring line PL) of the cell MC selected by the row decoder 120, the amount of electric charge corresponding to C×V=Q is stored in the output wiring line SL. Here, for example, as illustrated in FIG. 3, C corresponds to load capacitance cl corresponding to the polarization state (“0”) of the cell MC, or to load capacitance ch corresponding to the polarization state (“1”) of the cell MC. That is, it is possible to perform a “product” of the input (for example, a signal of a previous stage) of a neural network represented by Convolution Neural Network (CNN) and a parameter of the neural network in the multiply-accumulate operation circuit 110.

Note that in the case where the polarization state of the ferroelectric capacitor Cs is “1”, if the voltage applied to the capacitor Cs varies as 0 (V)→Va (V)→0 (V), the polarization state of the capacitor Cs becomes “0”. In addition, in the case where the polarization state of the ferroelectric capacitor Cs is “0”, if the voltage applied to the capacitor Cs varies as 0 (V)→Va (V)→0 (V), the polarization state of the capacitor Cs becomes “0” which is the same state as the state before the transition. Thus, in the multiply-accumulate operation circuit 110, the data held in the cell MC can be destroyed when the data is read in some cases.

FIG. 4 illustrates an example of a plan layout of the multiply-accumulate operation circuit 110. The multiple bit lines BL and the multiple input wiring lines PL both have wiring lines extending in a first direction, and these wiring lines are disposed alternately in a second direction. The second direction is orthogonal to the first direction. Two input wiring lines PL adjacent to each other are coupled to each other by an electrically conductive layer M, and correspond to one input wiring line PL of FIG. 2 described above. The multiple word lines WL extend in the second direction, and are arranged in the first direction at predetermined intervals.

A bit contact N is coupled to the bit line BL and the one source and drain terminal of the transistor Tr. The bit contact N is disposed at a position where the bit line BL and the one source and drain terminal of the transistor Tr are opposed to each other. The ferroelectric capacitor Cs is provided between the other source and drain terminal of the transistor Tr and the input wiring line PL. The ferroelectric capacitor Cs is disposed at a position where the input wiring line PL and the other source and drain terminal of the transistor Tr are opposed to each other.

Multiple bit contacts N and multiple ferroelectric capacitors Cs are disposed alternately in the first direction. The transistor Tr is provided to extend in a third direction coupling the bit contact N and the ferroelectric capacitor Cs. In the transistor Tr, the one source and drain terminal and the other source and drain terminal are disposed to be opposed to each other in the third direction.

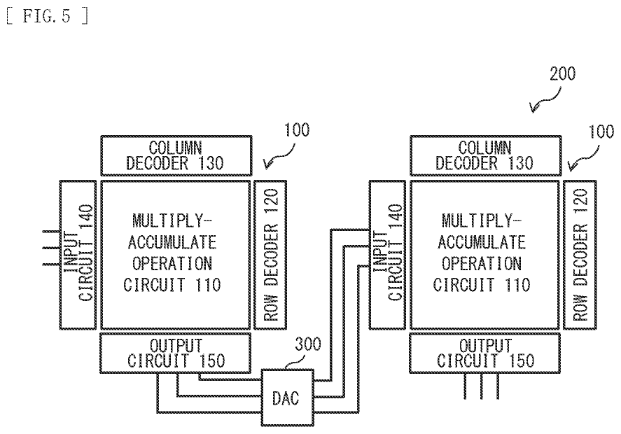

FIG. 5 illustrates an example of a configuration of a neural network 200 using two multiply-accumulate operation devices 100. The neural network 200 includes the two multiply-accumulate operation devices 100 and a DAC 300. The DAC 300 performs DA (Digital-to-Analog) conversion on multiple digital signals supplied from the output circuit 150 of the multiply-accumulate operation device 100 in the previous stage and supplies them to the input circuit 140 of the multiply-accumulate operation device 100 in the subsequent stage. It is possible to construct the neural network by thus coupling the two multiply-accumulate operation devices 100 via the DAC 300. Note that it is also possible to construct a neural network with use of multiple multiply-accumulate operation devices 100. In this case, the DAC 300 is provided between the multiply-accumulate operation device 100 on the previous stage side and the multiply-accumulate operation device 100 on the subsequent stage side.

### [Operation]

Next, a description is given of an operation of the multiply-accumulate operation device 100. In the present embodiment, in a case where the row decoder 120 selects a particular word line WL, where the input circuit 140 applies a positive voltage to a particular input wiring line PL as the input voltage Vp1, and where the column decoder 130 applies a ground voltage to a particular bit line BL as the voltage Vb1, electric charge corresponding to C×V=Q is supplied to the input wiring line PL from the cell MC (the cell MC to be accessed) coupled to the selected word line WL, the input wiring line PL to which the positive voltage is applied as the input voltage Vp1, and the bit line BL to which the ground voltage is applied as the voltage Vb1. As a result, the electric charge corresponding to C×V=Q is stored in the output wiring line SL coupled to the cell MC to be accessed. A voltage corresponding to the stored electric charge is generated in the output wiring line SL. This voltage of the output wiring line SL is subjected to AD conversion in the output circuit 150, and supplied to the outside.

The electric charge corresponding to C×V=Q is supplied to one output wiring line SL from each of the cells MC sharing the output wiring line SL by the row decoder 120 sequentially selecting the multiple word lines WL. Thus, a voltage corresponding to the sum of electric charges supplied from the respective cells MC sharing the output wiring line SL is generated in the output wiring line SL. This voltage of the output wiring line SL is subjected to AD conversion in the output circuit 150, and supplied to the outside from the output circuit 150. Such a reading operation is performed for each of the output wiring lines SL. The voltage (the multiply-accumulate operation result) corresponding to the sum of the electric charges supplied from the respective cells MC sharing the output wiring line SL is thereby supplied from the output circuit 150 to the outside for each of the output wiring lines SL.

### [Effects]

Next, a description is given of effects of the multiply-accumulate operation device 100. In the present embodiment, the ferroelectric capacitor Cs is provided in the cell MC. This allows a parameter (a weight) to be held in the ferroelectric capacitor Cs. Here, in a case where the variation in the load capacitance cl and the load capacitance ch is great, the variation causes a noise at the time of inference. This can decrease accuracy of the inference. However, in the present embodiment, the variation in the load capacitance cl and the load capacitance ch in the ferroelectric capacitors Cs that each hold the parameter (the weight) is small. It is therefore possible to perform the inference with high accuracy. In addition, the cell MC of 1T1C using the ferroelectric capacitor Cs is providable in a small area on a silicon substrate as compared with a multiply-accumulate operation cell using another memory (for example, a ReRAM). Accordingly, it is possible to provide the multiply-accumulate operation device 100 at a low cost. In addition, the upper limit of the number of times of rewriting in the ferroelectric capacitor Cs is extremely large as compared with a case of using another memory (for example, a ReRAM). Thus, the ferroelectric capacitor Cs practically has no limit in the number of times of rewriting.

In the present embodiment, the output circuit 150 is provided. The output circuit 150 performs AD conversion on the voltage corresponding to the electric charge stored in each of the output wiring lines PL and outputs the voltage subjected to the AD conversion. It is thus possible to construct a neural network by providing the ADC between the multiply-accumulate operation device 100 on the previous stage side and the multiply-accumulate operation device 100 on the subsequent stage side in a case of constructing the neural network with use of multiple multiply-accumulate operation devices 100.

In the present embodiment, each of the transistors Tr extends in an oblique direction intersecting with both a row direction and a column direction of the multiple cells MC. In each of the transistors Tr, the source and drain terminals in a pair are disposed to be opposed to each other in the oblique direction. This allows the multiply-accumulate operation circuit 110 to be provided in a rectangular shape on a surface of a semiconductor substrate, making it possible to improve the degree of freedom in designing.

In the present embodiment, the input wiring line PL is disposed at a position opposed to the one source and drain terminal with the ferroelectric capacitor Cs interposed therebetween. The output wiring line SL is disposed at a position opposed to the other source and drain terminal. This allows the multiply-accumulate operation circuit 110 to be provided in a rectangular shape on the surface of the semiconductor substrate, making it possible to improve the degree of freedom in designing.

### 3. Second Embodiment

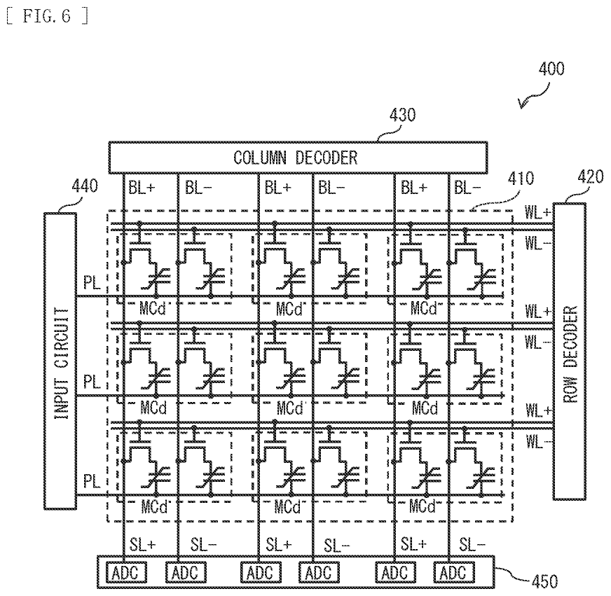

Next, a description is given of a multiply-accumulate operation device 400 according to a second embodiment of the present disclosure. FIG. 6 illustrates an example of a configuration of the multiply-accumulate operation device 400. The multiply-accumulate operation device 400 includes a multiply-accumulate operation circuit 410, a row decoder 420, a column decoder 430, an input circuit 440, and an output circuit 450. The multiply-accumulate operation circuit 410 includes multiple cells MCd that are coupled to each other in rows and columns. The multiple cells MCd correspond to synapses. The multiply-accumulate operation circuit 410 is driven by the row decoder 420, the column decoder 430, and the input circuit 440. The multiply-accumulate operation circuit 410 is provided on a silicon substrate, for example.

Multiple word lines WL+ and WL− are coupled to the row decoder 420. The multiple word lines WL+ are assigned with respect to the multiple cells MCd arranged in rows and columns, for example, in such a manner that each of the multiple word lines WL+ is assigned to corresponding one of the rows. The multiple word lines WL− are assigned with respect to the multiple cells MCd arranged in rows and columns, for example, in such a manner that each of the multiple word lines WL− is assigned to corresponding one of the rows. In other words, multiple sets each including the world lines WL+ and WL− are assigned with respect to the multiple cells MCd arranged in rows and columns, for example, in such a manner that each of the multiple sets is assigned to corresponding one of the rows. Multiple bit lines BL+ and BL− are coupled to the column decoder 430. The multiple bit lines BL+ are assigned with respect to the multiple cells MCd arranged in rows and columns, for example, in such a manner that each of the multiple bit lines BL+ is assigned to corresponding one of the columns. The multiple bit lines BL− are assigned with respect to the multiple cells MCd arranged in rows and columns, for example, in such a manner that each of the multiple bit lines BL− is assigned to corresponding one of the columns. In other words, multiple sets each including the bit lines BL+ and BL− are assigned with respect to the multiple cells MCd arranged in rows and columns, for example, in such a manner that each of the multiple sets is assigned to corresponding one of the rows. Multiple input wiring lines PL are coupled to the input circuit 440. The multiple input wiring lines PL are assigned with respect to the multiple cells MCd arranged in rows and columns, for example, in such a manner that each of the multiple input wiring lines PL is assigned to corresponding one of the rows. Multiple output wiring lines SL+ are each coupled to corresponding one of the bit lines BL+. Multiple output wiring lines SL− are each coupled to corresponding one of the bit lines BL−. The bit line BL− and the output wiring line SL− are configured to store an amount of electric charge corresponding to a product of capacitance of a ferroelectric capacitor Cs1 of each of the cells MC1 and an input voltage supplied to the input wiring line PL.

The multiply-accumulate operation circuit 410 includes the multiple cells MCd arranged in rows and columns. For example, as illustrated in FIG. 7, each of the cells MCd has a 2Tr2C circuit configuration that is configured to include two cells MC (cells MC1 and MC2). In each of the cells MCd, the cell MC1 is a main cell and the cell MC2 is a reference cell. In a case where a predetermined state is set to the cell MC1, an inverted state of the state of the cell MC1 is set to the cell MC2. The role of the reference cell will be described later in detail.

The cells MC1 and MC2 have configurations and functions similar to those of the cell MC according to the embodiment described above. The cell MC1 has, for example, a 1Tr1C circuit configuration that is configured to include a transistor Tr1 and a ferroelectric capacitor Cs1 coupled to a source and drain terminal of the transistor Tr1. The cell MC2 has, for example, a 1Tr1C circuit configuration that is configured to include a transistor Tr2 and a ferroelectric capacitor Cs2 coupled to a source and drain terminal of the transistor Tr2. The transistors Tr1 and Tr2 are MOSFETs, for example. The ferroelectric capacitors Cs1 and Cs2 each have a configuration in which a ferroelectric material is sandwiched between a pair of electrodes.

A gate of the transistor Tr1 is coupled to the word line WL−, and receives a signal from the row decoder 420 via the word line WL−. One source and drain terminal of the transistor Tr1 is coupled to the input wiring line PL via the ferroelectric capacitor Cs1. One terminal of the ferroelectric capacitor Cs1 is coupled to the one source and drain terminal of the transistor Tr1, and another terminal of the ferroelectric capacitor Cs1 is coupled to the input wiring line PL. The one source and drain terminal of the transistor Tr1 receives a signal from the input circuit 440 via the ferroelectric capacitor Cs1. The bit line BL− is coupled to the other source and drain terminal of the transistor Tr1, and the other source and drain terminal of the transistor Tr1 receives a signal from the column decoder 430 via the bit line BL−.

A gate of the transistor Tr2 is coupled to the word line WL+, and receives a signal from the row decoder 420 via the word line WL+. One source and drain terminal of the transistor Tr2 is coupled, via the ferroelectric capacitor Cs2, to the input wiring line PL to which the ferroelectric capacitor Cs1 is coupled. One terminal of the ferroelectric capacitor Cs2 is coupled to the one source and drain terminal of the transistor Tr2, and another terminal of the ferroelectric capacitor Cs2 is coupled to the input wiring line PL to which the ferroelectric capacitor Cs1 is coupled. In other words, in the cell MCd, the ferroelectric capacitors Cs1 and Cs2 are coupled to the common input wiring line PL. The one source and drain terminal of the transistor Tr2 receives a signal from the input circuit 440 via the ferroelectric capacitor Cs2. The bit line BL+ is coupled to the other source and drain terminal of the transistor Tr2, and the other source and drain terminal of the transistor Tr2 receives a signal from the column decoder 430 via the bit line BL+.

The row decoder 420 selects a cell MCd (or a cell MC1) to be accessed by applying a selection signal to the word line WL−. The selection signal is a pulse having a peak value higher than or equal to a threshold voltage of the transistor Tr1. In the cell MC1 selected by the row decoder 420, the transistor Tr1 is brought into a conductive state (is turned on). The column decoder 430 supplies a predetermined voltage Vbl1 to each of the cells MC1 coupled to the bit line BL− by applying the predetermined voltage Vbl1 to the bit line BL−. A voltage corresponding to a difference between the input voltage Vp1 applied to the input wiring line PL and the voltage Vbl1 applied to the bit line BL− is applied to each of the cells MC1.

The row decoder 420 selects a cell MCd (or a cell MC2) to be accessed by applying a selection signal to the word line WL+. The selection signal is a pulse having a peak value higher than or equal to a threshold voltage of the transistor Tr2. In the cell MC2 selected by the row decoder 420, the transistor Tr2 is brought into a conductive state (is turned on). The column decoder 430 supplies a predetermined voltage Vb12 to each of the cells MC2 coupled to the bit line BL+ by applying the predetermined voltage Vb12 to the bit line BL+. A voltage corresponding to a difference between the input voltage Vp1 applied to the input wiring line PL and the voltage Vb12 applied to the bit line BL+ is applied to each of the cells MC2.

Here, assume that, in a case where the input voltage Vp1 is a predetermined positive voltage, the voltage Vbl1 is, for example, a ground voltage (0 V). In this case, for example, “0” is stored in the cell MC1 as a polarization state of the cell MC1. In addition, assume that the voltage Vbl1 is a predetermined positive voltage in a case where the input voltage Vp1 is the ground voltage (0 V). In this case, for example, “1” is stored in the cell MC1 as the polarization state of the cell MC1.

Further, assume that, in a case where the input voltage Vp1 is a predetermined positive voltage, the voltage Vb12 is, for example, the ground voltage (0 V). In this case, for example, “0” is stored in the cell MC2 as a polarization state of the cell MC2. In addition, assume that the voltage Vb12 is a predetermined positive voltage in a case where the input voltage Vp1 is the ground voltage (0 V). In this case, for example, “1” is stored in the cell MC2 as the polarization state of the cell MC2.

The input voltage Vp1 is applied to the cell MC1 from the input circuit 440 through the input wiring line PL, and the voltage Vbl1 is applied to the cell MC1 from the column decoder 430 through the bit line BL−. As a result, a switching current corresponding to the polarization of the ferroelectric body of the cell MC1 flows through the cell MC1. The output of each of the cells MC1 is coupled to the output wiring line SL− via the bit line BL−. The output circuit 450 acquires a multiply-accumulate operation result by measuring a current flowing through the output wiring line SL− or a potential of the output wiring line SL−. For example, the output circuit 450 includes an AD conversion circuit that measures the respective voltages of the output wiring lines SL− at the same time and in parallel, and outputs, to an outside, a digital signal obtained by performing AD conversion on the multiply-accumulate operation result. Note that the output circuit 450 may further include an amplifier circuit or the like on an as-needed basis.

In the multiply-accumulate operation circuit 410, for example, when the voltage (the input voltage Vp1) is applied to the input (the input wiring line PL) of the cell MC1 selected by the row decoder 420, an amount of electric charge corresponding to the product of the capacitance of the ferroelectric capacitor Cs1 and the input voltage Vp1 is stored in the output wiring line SL−. It is thus possible to perform a multiply-accumulate operation. For example, in inference of the multiply-accumulate operation, when the voltage (the input voltage Vp1) is applied to the input (the input wiring line PL) of the cell MC1 selected by the row decoder 420, the amount of electric charge corresponding to C×V=Q is stored in the output wiring line SL−. Here, for example, as illustrated in FIG. 3, C corresponds to load capacitance cl corresponding to the polarization state (“0”) of the cell MC1, or to load capacitance ch corresponding to the polarization state (“1”) of the cell MC1. That is, it is possible to perform a “product” of the input (for example, a signal of a previous stage) of a neural network represented by Convolution Neural Network (CNN) and a parameter of the neural network in the multiply-accumulate operation circuit 110.

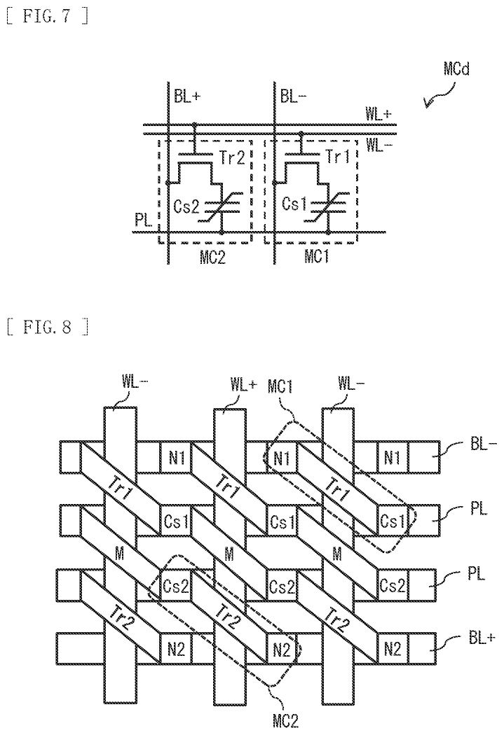

FIG. 8 illustrates an example of a plan layout of the multiply-accumulate operation circuit 410. The multiple bit lines BL− and BL+ and the multiple input wiring lines PL have wiring lines extending in a first direction, and these wiring lines are disposed in order of the bit line BL−, two input wiring lines PL, and the bit line BL+ repeatedly in a second direction. The second direction is orthogonal to the first direction. The two input wiring lines PL adjacent to each other are coupled to each other by an electrically conductive layer M, and correspond to one input wiring line PL of FIG. 7 described above. The multiple word lines WL+ and WL− extend in the second direction, and are disposed alternately in the first direction.

A bit contact N1 is coupled to the bit line BL− and the one source and drain terminal of the transistor Tr1. The bit contact N1 is disposed at a position where the bit line BL− and the one source and drain terminal of the transistor Tr1 are opposed to each other. The ferroelectric capacitor Cs1 is provided between the other source and drain terminal of the transistor Tr1 and the input wiring line PL. The ferroelectric capacitor Cs1 is disposed at a position where the input wiring line PL and the other source and drain terminal of the transistor Tr are opposed to each other.

A bit contact N2 is coupled to the bit line BL+ and the one source and drain terminal of the transistor Tr2. The bit contact N2 is disposed at a position where the bit line BL+ and the one source and drain terminal of the transistor Tr2 are opposed to each other. The ferroelectric capacitor Cs2 is provided between the other source and drain terminal of the transistor Tr2 and the input wiring line PL. The ferroelectric capacitor Cs2 is disposed at a position where the input wiring line PL and the other source and drain terminal of the transistor Tr2 are opposed to each other.

Multiple bit contacts N1 and N2 and multiple ferroelectric capacitors Cs1 and Cs2 are disposed in order of the bit contact N1, the ferroelectric capacitor Cs1, the ferroelectric capacitor Cs2, and the bit contact N2 repeatedly in the first direction. The transistor Tr1 is provided to extend in a third direction intersecting with the first direction and the second direction. In the transistor Tr1, the one source and drain terminal and the other source and drain terminal are disposed to be opposed to each other in the third direction. The transistor Tr2 is provided to extend in the third direction intersecting with the first direction and the second direction. In the transistor Tr2, the one source and drain terminal and the other source and drain terminal are disposed to be opposed to each other in the third direction.

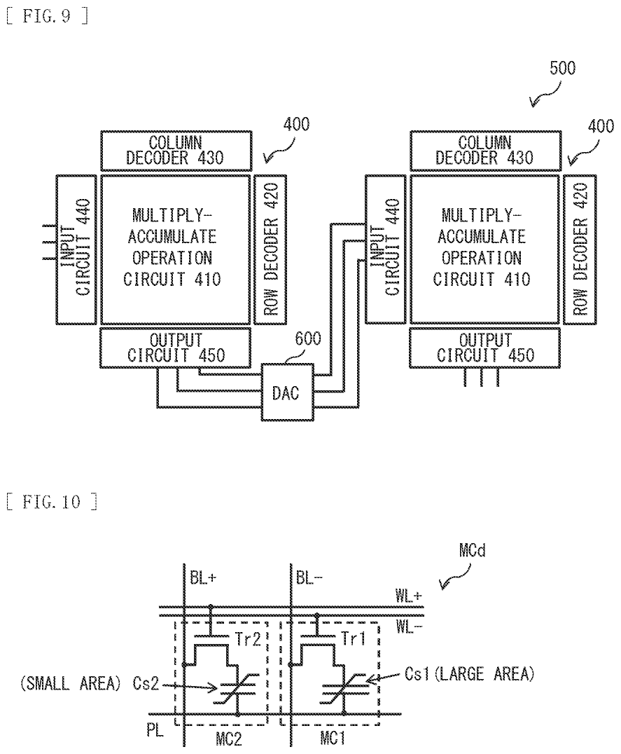

FIG. 9 illustrates an example of a configuration of a neural network 500 using two multiply-accumulate operation devices 400. The neural network 500 includes the two multiply-accumulate operation devices 400 and a DAC 600. The DAC 600 performs DA (Digital-to-Analog) conversion on multiple digital signals supplied from the output circuit 450 of the multiply-accumulate operation device 400 in the previous stage and supplies them to the input circuit 440 of the multiply-accumulate operation device 400 in the subsequent stage. It is possible to construct the neural network by thus coupling the two multiply-accumulate operation devices 400 via the DAC 600. Note that it is also possible to construct a neural network with use of multiple multiply-accumulate operation devices 400. In this case, the DAC 600 is provided between the multiply-accumulate operation device 400 on the previous stage side and the multiply-accumulate operation device 400 on the subsequent stage side.

### [Operation]

Next, a description is given of an operation of the multiply-accumulate operation device 400. In the present embodiment, in a case where the row decoder 420 selects a particular word line WL−, where the input circuit 140 applies a positive voltage to a particular input wiring line PL as the input voltage Vp1, and where the column decoder 130 applies a ground voltage to a particular bit line BL− as the voltage Vb1, electric charge corresponding to C×V=Q is supplied to the output wiring line SL from the cell MC1 (the cell MC1 to be accessed) coupled to the selected word line WL−, the input wiring line PL to which the positive voltage is applied as the input voltage Vp1, and the bit line BL− to which the ground voltage is applied as the voltage Vb1. As a result, the electric charge corresponding to C×V=Q is stored in the output wiring line SL− coupled to the cell MC1 to be accessed. A voltage corresponding to the stored electric charge is generated in the output wiring line SL−. This voltage of the output wiring line SL− is subjected to AD conversion in the output circuit 450, and supplied to the outside.

The electric charge corresponding to C×V=Q is supplied to one output wiring line SL− from each of the cells MC1 sharing the output wiring line SL− by the row decoder 420 sequentially selecting the multiple word lines WL−. Thus, a voltage corresponding to the sum of electric charges supplied from the respective cells MC1 sharing the output wiring line SL− is generated in the output wiring line SL−. This voltage of the output wiring line SL− is subjected to AD conversion in the output circuit 450, and supplied to the outside from the output circuit 450. Such a reading operation is performed for each of the output wiring lines SL−. The voltage (the multiply-accumulate operation result) corresponding to the sum of electric charges supplied from the respective cells MC1 sharing the output wiring line SL− is thereby supplied from the output circuit 450 to the outside for each of the output wiring lines SL−.

Incidentally, in the multiply-accumulate operation circuit 110, the data held in the cell MC can be destroyed when the data is read in some cases, as described above. To address this, in the multiply-accumulate operation circuit 110, the cell MC2 which is the reference cell has a function of backing up the cell MC1. For example, the multiply-accumulate operation circuit 110 writes “1” in the cell MC1 as a state, writes “0”, which is an inverted state of the state of the cell MC1, in the cell MC2, and thereafter performs inference of a multiply-accumulate operation. In this case, the inference of the multiply-accumulate operation results in destructive readout. Therefore, the cell MC1 becomes “0”. Thereafter, the multiply-accumulate operation device 400 writes, in the cell MC1, an inverted state (“1”) of the state (“0”) read from the cell MC2. Rewriting in the cell MC1 is thus performed. Such rewriting is achievable by causing the cell MC2 to serves as a backup of the cell MC1.

### [Effects]

Next, a description is given of effects of the multiply-accumulate operation device 400. In the present embodiment, the ferroelectric capacitors Cs1 and Cs2 are provided in the cell MC. This allows the parameter (the weight) to be held in the ferroelectric capacitors Cs1 and Cs2. Here, in a case where the variation in the load capacitance cl and the load capacitance ch is great, the variation causes a noise at the time of inference. This can decrease accuracy of the inference. However, in the present embodiment, the variation in the load capacitance cl and the load capacitance ch in the ferroelectric capacitors Cs1 and Cs2 that each hold the parameter (the weight) is small. It is therefore possible to perform the inference with high accuracy. In addition, the cell MC1 of 1T1C using the ferroelectric capacitor Cs1 and the cell MC2 of 1T1C using the ferroelectric capacitor Cs2 are providable with a small area on a silicon substrate as compared with a multiply-accumulate operation cell using another memory (for example, a ReRAM). Accordingly, it is possible to provide the multiply-accumulate operation device 100 at a low cost. In addition, the upper limit of the number of times of rewriting in the ferroelectric capacitors Cs1 and Cs2 is extremely large as compared with a case of using another memory (for example, a ReRAM). Thus, the ferroelectric capacitors Cs1 and Cs2 practically have no limit in the number of times of rewriting.

In the present embodiment, the output circuit 450 is provided. The output circuit 450 performs AD conversion on the voltage corresponding to the electric charge stored in each of the output wiring lines PL and outputs the voltage subjected to the AD conversion. It is thus possible to construct a neural network by providing the ADC between the multiply-accumulate operation device 400 on the previous stage side and the multiply-accumulate operation device 400 on the subsequent stage side in a case of constructing the neural network with use of multiple multiply-accumulate operation devices 400.

In the present embodiment, each of the transistors Tr1 and Tr2 extends in an oblique direction intersecting with both a row direction and a column direction of the multiple cells MCd. In each of the transistors Tr1 and Tr2, the source and drain terminals in a pair are disposed to be opposed to each other in the oblique direction. This allows the multiply-accumulate operation circuit 410 to be provided in a rectangular shape on a surface of a semiconductor substrate, making it possible to improve the degree of freedom in designing.

In the present embodiment, the input wiring line PL is disposed at a position opposed to the one source and drain terminal with the ferroelectric capacitor Cs1 or Cs2 interposed therebetween. The output wiring line SL− is disposed at a position opposed to the other source and drain terminal. This allows the multiply-accumulate operation circuit 410 to be provided in a rectangular shape on the surface of the semiconductor substrate, making it possible to improve the degree of freedom in designing.

### 3. Modifications of Second Embodiment

In the second embodiment described above, for example, as illustrated in FIG. 10, the area of the ferroelectric capacitor Cs1 included in the cell MC1 and the area of the ferroelectric capacitor Cs2 included in the cell MC2 may be different from each other.

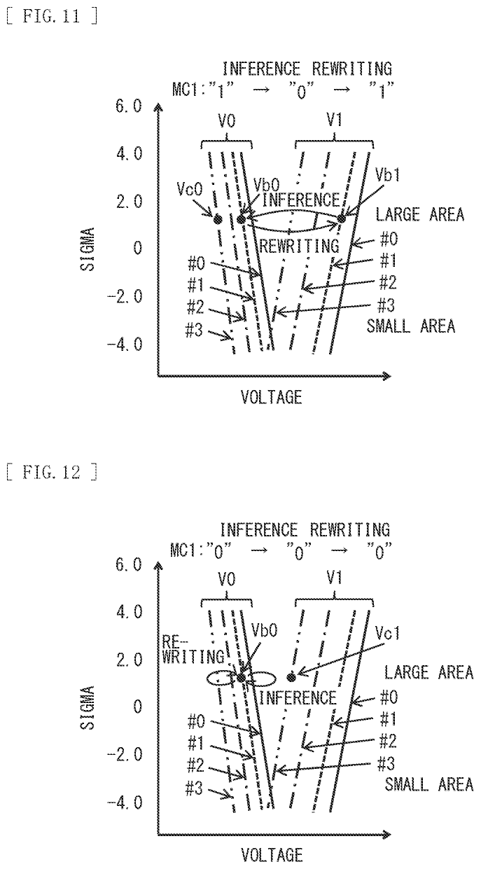

FIGS. 11 and 12 each illustrate an example of distributions of a voltage V0 for “0” and a voltage V1 for “1” that are read from each of the cells MC in a 64k bit cell array. FIGS. 11 and 12 each illustrate the example of the distributions of the voltages V0 and V1 in cases where the area of the ferroelectric capacitor Cs1 included in the cell MC1 are #0, #1, #2, and #3. In the following, the voltage V1 at a time when “1” is held in the cell MC1 having the area of #1 is assumed to be Vb1, the voltage V0 at a time when “0” is held in the cell MC1 having the area of #1 is assumed to be Vb0, the voltage V1 at a time when “1” is held in the cell MC1 having the area of #3 is assumed to be Vc1, and the voltage V0 at a time when “0” is held in the cell MC1 having the area of #3 is assumed to be Vc0. In the following, a description is given of a multiply-accumulate operation in a case where the area of the cell MC1 is #1 and the area of the cell MC2 is #3.

A control device that controls the multiply-accumulate operation device 400 writes “1” in the cell MC1, writes “0” in the cell MC2, and thereafter performs inference of the multiply-accumulate operation. In this case, the inference of the multiply-accumulate operation results in a destructive readout. Therefore, the cell MC1 becomes “0” (FIG. 11). Thereafter, the control device that controls the multiply-accumulate operation device 400 reads “0” from the cell MC1, reads “0” from the cell MC2, and compares the voltage Vb0 obtained from the cell MC1 and the voltage Vc0 obtained from the cell MC2 with each other. If it is confirmed that Vb0>Vc0 is satisfied, the control device writes “1” in the cell MC1 (FIG. 11). Rewriting in the cell MC1 is thus performed. Such rewriting is achievable by causing the cell MC2 to serve as a backup of the cell MC1.

The control device that controls the multiply-accumulate operation device 400 writes “0” in the cell MC1, writes “1” in the cell MC2, and thereafter performs the inference of the multiply-accumulate operation. In this case, the cell MC1 remains to be “0” (FIG. 12). Thereafter, the control device that controls the multiply-accumulate operation device 400 reads “0” from the cell MC1, reads “1” from the cell MC2, and compares the voltage Vb0 obtained from the cell MC1 and the voltage Vc1 obtained from the cell MC2 with each other. If it is confirmed that Vb0<Vc1 is satisfied, the control device writes “0” in the cell MC1 (FIG. 12). Rewriting in the cell MC1 is thus performed. Such rewriting is achievable by causing the cell MC2 to serve as a backup of the cell MC1.

Although the present disclosure has been described above with reference to some embodiments and modifications thereof, the present disclosure is not limited to the embodiments and the like described above, and various modifications may be made. It should be noted that the effects described herein are mere examples. The effects of the present disclosure are not limited to the effects described herein. The present disclosure may have effects other than the effects described herein.

In each of the embodiments and the modifications thereof described above, the bit line BL itself may also serve as the output wiring line PL. Further, in the first embodiment and the modification thereof described above, each of the multiple input wiring lines PL may be assigned to corresponding one of the rows of the multiple cells MC, or each unit of two of the multiple input wiring lines PL may be assigned to corresponding one of the rows of the multiple cells MC. Further, in the second embodiment and the modification thereof described above, each of the multiple input wiring lines may be assigned to corresponding one of the rows of the multiple cells MC, or each unit of two of the multiple input wiring lines may be assigned to corresponding one of the rows of the multiple cells MC.

In addition, for example, the present disclosure may have any of the following configurations.

(1)

A multiply-accumulate operation device including:
multiple cells each including a transistor and a ferroelectric capacitor that is coupled to a first source and drain terminal of the transistor, the multiple cells being arranged in rows and columns;
multiple input wiring lines each unit of one or more of which is assigned to corresponding one of the rows of the multiple cells, the multiple input wiring lines being coupled to the ferroelectric capacitors; and
multiple output wiring lines each of which is assigned to corresponding one of the columns of the multiple cells, the multiple output wiring lines being coupled to second source and drain terminals of the transistors, the multiple output wiring lines each being configured to store an amount of electric charge corresponding to a product of capacitance of the ferroelectric capacitor of each of the cells and an input voltage supplied to the input wiring line.
   (2)

The multiply-accumulate operation device according to (1), further including an output circuit that performs AD conversion on a voltage corresponding to the electric charge stored in each of the output wiring lines and outputs the voltage subjected to the AD conversion.

(3)

The multiply-accumulate operation device according to (1) or (2), in which
each of the transistors extends in an oblique direction intersecting with both a row direction and a column direction of the multiple cells, and
in each of the transistors, the first source and drain terminal and the second source and drain terminal are disposed to be opposed to each other in the oblique direction.
   (4)

The multiply-accumulate operation device according to (3), in which
the input wiring line is disposed at a position opposed to the first source and drain terminal with the ferroelectric capacitor interposed therebetween, and
the output wiring line is disposed at a position opposed to the second source and drain terminal.
   (5)

A multiply-accumulate operation device including:
multiple cells each including a main cell and a reference cell, the multiple cells being arranged in rows and columns, the main cell including a first transistor and a first ferroelectric capacitor that is coupled to a first source and drain terminal of the first transistor, the reference cell including a second transistor and a second ferroelectric capacitor that is coupled to a second source and drain terminal of the second transistor;
multiple input wiring lines each unit of one or more of which is assigned to corresponding one of the rows of the multiple cells, the multiple input wiring lines being coupled to the first ferroelectric capacitors and the second ferroelectric capacitors;
multiple first output wiring lines each of which is assigned to corresponding one of the columns of the multiple cells, the multiple first output wiring lines being coupled to third source and drain terminals of the first transistors, the multiple first output wiring lines each being configured to store an amount of electric charge corresponding to a product of capacitance of the first ferroelectric capacitor of each of the main cells and an input voltage supplied to the input wiring line; and
multiple second output wiring lines each of which is assigned to corresponding one of the columns of the multiple cells, the multiple second output wiring lines being coupled to fourth source and drain terminals of the second transistors, the multiple second output wiring lines each being configured to store an amount of electric charge corresponding to a product of capacitance of the second ferroelectric capacitor of each of the reference cells and the input voltage supplied to the input wiring line.
   (6)

The multiply-accumulate operation device according to (5), further including an output circuit that performs AD conversion on a voltage corresponding to the electric charge stored in each of the first output wiring lines and outputs the voltage subjected to the AD conversion.

(7)

The multiply-accumulate operation device according to (5) or (6), in which
each of the first transistors and each of the second transistors extend in an oblique direction intersecting with both a row direction and a column direction of the multiple cells,
in each of the first transistors, the first source and drain terminal and the third source and drain terminal are disposed to be opposed to each other in the oblique direction, and
in each of the second transistors, the second source and drain terminal and the fourth source and drain terminal are disposed to be opposed to each other in the oblique direction.
   (8)

The multiply-accumulate operation device according to (7), in which
each unit of two of the multiple input wiring lines is assigned to corresponding one of the rows of the multiple cells, and
in each unit of two of the input wiring lines assigned to corresponding one of the rows of the multiple cells, a first input wiring line is disposed at a position opposed to the first source and drain terminal with the first ferroelectric capacitor interposed therebetween, and a second input wiring line is disposed at a position opposed to the second source and drain terminal.
   (9)

The multiply-accumulate operation device according to any one of (5) to (8), in which an area of the first ferroelectric capacitor and an area of the second ferroelectric capacitor are different from each other.

(10)

A neural network including
multiple multiply-accumulate operation devices, in which
each of the multiply-accumulate operation devices includes
   multiple cells each including a transistor and a ferroelectric capacitor that is coupled to a first source and drain terminal of the transistor, the multiple cells being arranged in rows and columns,
   multiple input wiring lines each unit of one or more of which is assigned to corresponding one of the rows of the multiple cells, the multiple input wiring lines being coupled to the ferroelectric capacitors, and
   multiple output wiring lines each of which is assigned to corresponding one of the columns of the multiple cells, the multiple output wiring lines being coupled to second source and drain terminals of the transistors, the multiple output wiring lines each being configured to store an amount of electric charge corresponding to a product of capacitance of the ferroelectric capacitor of each of the cells and an input voltage supplied to the input wiring line.
      (11)

A neural network including
multiple multiply-accumulate operation devices, in which
each of the multiply-accumulate operation devices includes
   multiple cells each including a main cell and a reference cell, the multiple cells being arranged in rows and columns, the main cell including a first transistor and a first ferroelectric capacitor that is coupled to a first source and drain terminal of the first transistor, the reference cell including a second transistor and a second ferroelectric capacitor that is coupled to a second source and drain terminal of the second transistor,
   multiple input wiring lines each unit of one or more of which is assigned to corresponding one of the rows of the multiple cells, the multiple input wiring lines being coupled to the first ferroelectric capacitors and the second ferroelectric capacitors,
   multiple first output wiring lines each of which is assigned to corresponding one of the columns of the multiple cells, the multiple first output wiring lines being coupled to third source and drain terminals of the first transistors, the multiple first output wiring lines each being configured to store an amount of electric charge corresponding to a product of capacitance of the first ferroelectric capacitor of each of the main cells and an input voltage supplied to the input wiring line, and
   multiple second output wiring lines each of which is assigned to corresponding one of the columns of the multiple cells, the multiple second output wiring lines being coupled to fourth source and drain terminals of the second transistors, the multiple second output wiring lines each being configured to store an amount of electric charge corresponding to a product of capacitance of the second ferroelectric capacitor of each of the reference cells and the input voltage supplied to the input wiring line.

In a multiply-accumulate operation device according to a first aspect of the present disclosure and a neural network according to a second aspect of the present disclosure, a ferroelectric capacitor is provided in a cell. This allows a parameter (a weight) to be held in the ferroelectric capacitor. Here, in a case where the variation in the load capacitance of the cells is great, the variation causes a noise at the time of inference. This can decrease accuracy of the inference. However, in the present disclosure, the variation in the load capacitance in the ferroelectric capacitors that each hold the parameter (the weight) is small. It is therefore possible to perform the inference with high accuracy. In addition, the upper limit of the number of times of rewriting in the ferroelectric capacitor is extremely large as compared with a case of using another memory (for example, a ReRAM). Thus, the ferroelectric capacitor practically has no limit in the number of times of rewriting. It is therefore possible to provide a multiply-accumulate operation device that is able to hold a parameter and also able to perform writing for the number of times acceptable for practical use.

In a multiply-accumulate operation device according to a third aspect of the present disclosure and a neural network according to a fourth aspect of the present disclosure, a ferroelectric capacitor is provided in each of a first cell and a second cell. This allows a parameter (a weight) to be held in the ferroelectric capacitor. Here, in a case where the variation in the load capacitance of the cells is great, the variation causes a noise at the time of inference. This can decrease accuracy of the inference. However, in the present disclosure, the variation in the load capacitance in the ferroelectric capacitors that each hold the parameter (the weight) is small. It is therefore possible to perform the inference with high accuracy. In addition, the upper limit of the number of times of rewriting in the ferroelectric capacitor is extremely large as compared with a case of using another memory (for example, a ReRAM). Thus, the ferroelectric capacitor practically has no limit in the number of times of rewriting. It is therefore possible to provide a multiply-accumulate operation device that is able to hold a parameter and also able to perform writing for the number of times acceptable for practical use.

This application claims the priority on the basis of Japanese Patent Application No. 2020-217286 filed on Dec. 25, 2020 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A multiply-accumulate operation device comprising:
multiple cells each including a transistor and a ferroelectric capacitor that is coupled to a first source and drain terminal of the transistor, the multiple cells being arranged in rows and columns;
multiple input wiring lines each unit of one or more of which is assigned to corresponding one of the rows of the multiple cells, the multiple input wiring lines being coupled to the ferroelectric capacitors; and
multiple output wiring lines each of which is assigned to corresponding one of the columns of the multiple cells, the multiple output wiring lines being coupled to second source and drain terminals of the transistors, the multiple output wiring lines each being configured to store an amount of electric charge corresponding to a product of capacitance of the ferroelectric capacitor of each of the cells and an input voltage supplied to the input wiring line.

2. The multiply-accumulate operation device according to claim 1, further comprising an output circuit that performs AD conversion on a voltage corresponding to the electric charge stored in each of the output wiring lines and outputs the voltage subjected to the AD conversion.

3. The multiply-accumulate operation device according to claim 1, wherein
each of the transistors extends in an oblique direction intersecting with both a row direction and a column direction of the multiple cells, and
in each of the transistors, the first source and drain terminal and the second source and drain terminal are disposed to be opposed to each other in the oblique direction.

4. The multiply-accumulate operation device according to claim 3, wherein
the input wiring line is disposed at a position opposed to the first source and drain terminal with the ferroelectric capacitor interposed therebetween, and
the output wiring line is disposed at a position opposed to the second source and drain terminal.

5. A multiply-accumulate operation device comprising:
multiple cells each including a main cell and a reference cell, the multiple cells being arranged in rows and columns, the main cell including a first transistor and a first ferroelectric capacitor that is coupled to a first source and drain terminal of the first transistor, the reference cell including a second transistor and a second ferroelectric capacitor that is coupled to a second source and drain terminal of the second transistor;
multiple input wiring lines each unit of one or more of which is assigned to corresponding one of the rows of the multiple cells, the multiple input wiring lines being coupled to the first ferroelectric capacitors and the second ferroelectric capacitors;
multiple first output wiring lines each of which is assigned to corresponding one of the columns of the multiple cells, the multiple first output wiring lines being coupled to third source and drain terminals of the first transistors, the multiple first output wiring lines each being configured to store an amount of electric charge corresponding to a product of capacitance of the first ferroelectric capacitor of each of the main cells and an input voltage supplied to the input wiring line; and
multiple second output wiring lines each of which is assigned to corresponding one of the columns of the multiple cells, the multiple second output wiring lines being coupled to fourth source and drain terminals of the second transistors, the multiple second output wiring lines each being configured to store an amount of electric charge corresponding to a product of capacitance of the second ferroelectric capacitor of each of the reference cells and the input voltage supplied to the input wiring line.

6. The multiply-accumulate operation device according to claim 5, further comprising an output circuit that performs AD conversion on a voltage corresponding to the electric charge stored in each of the first output wiring lines and outputs the voltage subjected to the AD conversion.

7. The multiply-accumulate operation device according to claim 5, wherein
each of the first transistors and each of the second transistors extend in an oblique direction intersecting with both a row direction and a column direction of the multiple cells,
in each of the first transistors, the first source and drain terminal and the third source and drain terminal are disposed to be opposed to each other in the oblique direction, and
in each of the second transistors, the second source and drain terminal and the fourth source and drain terminal are disposed to be opposed to each other in the oblique direction.

8. The multiply-accumulate operation device according to claim 7, wherein
each unit of two of the multiple input wiring lines is assigned to corresponding one of the rows of the multiple cells, and
in each unit of two of the input wiring lines assigned to corresponding one of the rows of the multiple cells, a first input wiring line is disposed at a position opposed to the first source and drain terminal with the first ferroelectric capacitor interposed therebetween, and a second input wiring line is disposed at a position opposed to the second source and drain terminal.

9. The multiply-accumulate operation device according to claim 5, wherein an area of the first ferroelectric capacitor and an area of the second ferroelectric capacitor are different from each other.

10. A neural network comprising
multiple multiply-accumulate operation devices, wherein
each of the multiply-accumulate operation devices includes
multiple cells each including a transistor and a ferroelectric capacitor that is coupled to a first source and drain terminal of the transistor, the multiple cells being arranged in rows and columns,
multiple input wiring lines each unit of one or more of which is assigned to corresponding one of the rows of the multiple cells, the multiple input wiring lines being coupled to the ferroelectric capacitors, and
multiple output wiring lines each of which is assigned to corresponding one of the columns of the multiple cells, the multiple output wiring lines being coupled to second source and drain terminals of the transistors, the multiple output wiring lines each being configured to store an amount of electric charge corresponding to a product of capacitance of the ferroelectric capacitor of each of the cells and an input voltage supplied to the input wiring line.

11. A neural network comprising
multiple multiply-accumulate operation devices, wherein
each of the multiply-accumulate operation devices includes
multiple cells each including a main cell and a reference cell, the multiple cells being arranged in rows and columns, the main cell including a first transistor and a first ferroelectric capacitor that is coupled to a first source and drain terminal of the first transistor, the reference cell including a second transistor and a second ferroelectric capacitor that is coupled to a second source and drain terminal of the second transistor,
multiple input wiring lines each unit of one or more of which is assigned to corresponding one of the rows of the multiple cells, the multiple input wiring lines being coupled to the first ferroelectric capacitors and the second ferroelectric capacitors,
multiple first output wiring lines each of which is assigned to corresponding one of the columns of the multiple cells, the multiple first output wiring lines being coupled to third source and drain terminals of the first transistors, the multiple first output wiring lines each being configured to store an amount of electric charge corresponding to a product of capacitance of the first ferroelectric capacitor of each of the main cells and an input voltage supplied to the input wiring line, and
multiple second output wiring lines each of which is assigned to corresponding one of the columns of the multiple cells, the multiple second output wiring lines being coupled to fourth source and drain terminals of the second transistors, the multiple second output wiring lines each being configured to store an amount of electric charge corresponding to a product of capacitance of the second ferroelectric capacitor of each of the reference cells and the input voltage supplied to the input wiring line.
